(19) United States
(12) Patent Application Publication
(10) Pub. No.: US 2010/0178611 A1
(43) Pub. Date: Jul. 15, 2010

(54) Lithography method of electron beam

(75) Inventors: Hirohito Anze, Shizuoka (JP); Takehiko Katsumata, Shizuoka (JP); Shuichi Tamamushi, Kanagawa (JP); Takashi Kamikubo, Kanagawa (JP); Rieko Nishimura, Kanagawa (JP); Makoto Hiramoto, Tokyo (JP); Tomoo Motosugi, Shizuoka (JP); Takazuki Ohnishi, Shizuoka (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: NuFlare Technology, Inc., Numazu-shi (JP)

(21) Appl. No.: 12/659,774

(22) Filed: Mar. 22, 2010

Related U.S. Application Data
(63) Continuation-in-part of application No. 11/734,587, filed on Apr. 12, 2007.

(30) Foreign Application Priority Data
Apr. 13, 2006 (JP) 2006-110592

(51) Int. Cl. G03F 7/20

(52) U.S. Cl. 430/296

(57) ABSTRACT

A charged particle beam writing method on a chemical amplification type resist, comprising: coating said chemical amplification type resist which contains an acid diffusion inhibitor, on a surface of a mask substrate, exposing charged particle beams to said chemical amplification type resist layer on said surface of the mask substrate, baking said chemical amplification type resist layer which said charged particle beams were exposed, and developing said chemical amplification type resist after the baking, wherein an exposure current density of said electron beams exposing ranges of 50^{˜}5000 A/cm², said photo acid generator is in an amount ranging from 0.1 to 30 weight percent (wt %) relative to all solid content of said chemical amplification type resist, and said acid diffusion inhibitor is composed of at least one material selected from the group consisting of tertiary amine class, benzyl-carbamate class, benzoin-carbamate class, o-carbamoyl-hydroxy-amine class, o-carbamoyl-oxime class, and dithio-calbamate-quaternary ammonium salt.

### CROSS-REFERENCE TO RELATED APPLICATION

This is a Continuation-in-Part application of U.S. patent application Ser. No. 11/734,587, filed Apr. 12, 2007, the entire contents of which are incorporated herein by reference.

This application is based upon and claims the benefit of priority from prior Japanese Patent Application No. JP2006-110592, filed on Apr. 13, 2006, the entire contents of which are incorporated herein by reference.

### BACKGROUND OF THE INVENTION

1. Field of the Invention

The present invention relates to a resist pattern forming method, in particular, by using a charged particle beam, and relates to a charged particle beam writing method.

2. Description of the Prior Art

In recent year, along with the improvement of integration of semiconductor devices, dimensional accuracy of patterns formed on the substrate of semiconductor etc. is much more required. In response to the requirements, various attempts, such as to shorten a light wavelength used in an exposure, a charged particle beam exposure, improvements of resist materials, and optimization of a lithography process etc., are carried out.

A chemical amplification type resist is widely used in the lithography process forming patterns on semiconductor substrates when semiconductor devices are manufactured. The chemical amplification type resist is a compound material made up of a base polymer resist and a photo acid generator. Through exposure, an acid is generated in the resist and by heating after the exposure; it is diffused within the resist. The acid acts as a catalyst and accelerates the solubilization reaction or insolubilization reaction of the resist. Through the reaction of the acid catalyst and the resist, the acid that acts as a catalyst of the solubilization reaction or insolubilization reaction of the resist resin is generated, and therefore, the lithography of high sensitive and low irradiance of light or an efficient energy beam irradiation is expected.

So described as above, in the chemical amplification type resist pattern forming method, generally, the acid is generated with low irradiance and following the bake process, the generated acid is accelerating the reaction as the catalyst of the solubilization or insolubilization of the resist resin. However, this forming method has a defect of reaching a ceiling of the dimensional accuracy of the resist pattern because under the exposure of low irradiance, the reaction area of a charged particle and an acid generator is sparse, and after the chemical amplification reaction, its influences still remain.

When the amount of irradiance of charged particle beams is increased, the probability of the reaction of the charged particle beams with the acid generator is improved, and also, the dimensional accuracy of the resist pattern may be improved. In order to increase the amount of irradiance of charged particle beams, it is necessary to increase the exposure time. But, to increase the exposure time is to decrease the throughput on the writing system. Therefore, the solution to the above problem is expected.

(Japanese Patent laid open No. 2003-140352)

### SUMMARY OF THE INVENTION

The present invention is to solve the above problem of a conventional lithography using a charged particle beam, and to actualize the excellent dimensional accuracy of resist patterns by means of shortening the effective acid diffusion length of a chemical amplification type resist without decreasing the throughput of a writing system.

The present invention features a system and method by means of increasing the amount of the acid diffusion inhibitor to shorten the effective acid diffusion length in the chemical amplification type resist, and also by means of increasing the exposure current density to protect the throughput drop of the writing system.

That is, the present invention provides a electron beam lithography method on a chemical amplification type resist, comprising: coating said chemical amplification type resist which contains an acid diffusion inhibitor, on a surface of a mask substrate, exposing electron beams to said chemical amplification type resist layer on said surface of the mask substrate, baking said chemical amplification type resist layer which said electron beams were exposed, and developing said chemical amplification type resist after the baking, wherein an exposure current density of said electron beams exposing ranges of 50^{˜}5000 A/cm², said photo acid generator is in an amount ranging from 0.1 to 30 weight percent (wt %) relative to all solid content of said chemical amplification type resist, and said acid diffusion inhibitor is composed of at least one material selected from the group consisting of tertiary amine class, benzyl-carbamate class, benzoin-carbamate class, o-carbamoyl-hydroxy-amine class, o-carbamoyl-oxime class, and dithio-calbamate-quaternary ammonium salt.

It is preferable that an alkaline developer is used in the development process to actualize latent images, which are formed on said resist.

### EFFECT OF THE INVENTION

The present invention having simple constitutions enable to form resist patterns of the excellent dimensional accuracy not decreasing throughput of the resist pattern forming.

### BRIEF DESCRIPTION OF THE DRAWINGS

FIG. 1A and FIG. 1B shows schematic diagrams illustrating the concept according to the present invention.

FIG. 2A and FIG. 2B shows schematic diagrams illustrating a typical situation example of the reaction in a conventional chemical amplification type resist.

FIG. 3 shows schematic diagrams illustrating a typical situation example of the reaction in the chemical amplification type resist according to the present invention.

FIG. 4 shows a schematic diagram illustrating an electron beam exposure system example according to the present invention.

FIG. 5A to FIG. 5D shows the cross-section photographs (cross sectional profile) of resist patterns of examples of the present invention that review effectiveness of the present invention.

### DETAILED DESCRIPTION OF THE INVENTION

The concept according to the present invention is explained as follows using figures.

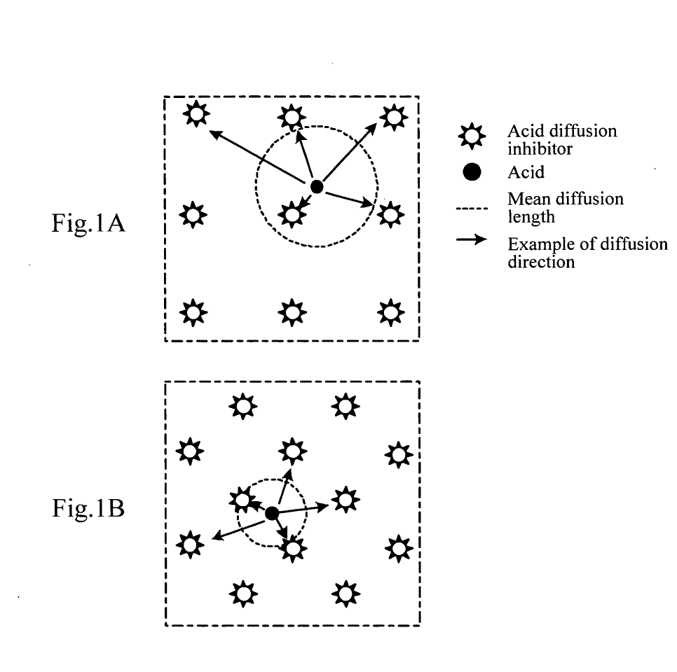

FIGS. 1A and B shows a schematic diagram illustrating the concept according to the present invention and shows typical situation examples of the reaction in a chemical amplification type resist which is caused by the charged particle beam exposure. FIG. 1A shows a typical situation example of the reaction in a conventional chemical amplification type resist that an acid diffusion inhibitor is added. In FIG. 1A, 9 acid diffusion inhibitors exist in the charged particle beams exposure area. In the center, charged particle beams collide with the resist and acids are generated from acid generators by resolving. (A closed circle in FIG. 1A shows the generated acid.) The acid is diffused by PEB(Post Exposure Bake) of lithography in arrow directions and collide with the acid diffusion inhibitor formulated in the resist and is inactivated. The mean diffusion length of the acid from the generation to the inactivation is shown in the dotted line circle in FIG. 1A. FIG. 1B shows the example of the present invention and its reaction. The amount of the acid diffusion inhibitors (FIG. 1B) increases and the existence of numbers of acid diffusion inhibitors increases probability of reaction with the acid, and the mean diffusion length of the acid generated by the charged particle beam exposure is shorter than the conventional example, FIG. 1A.

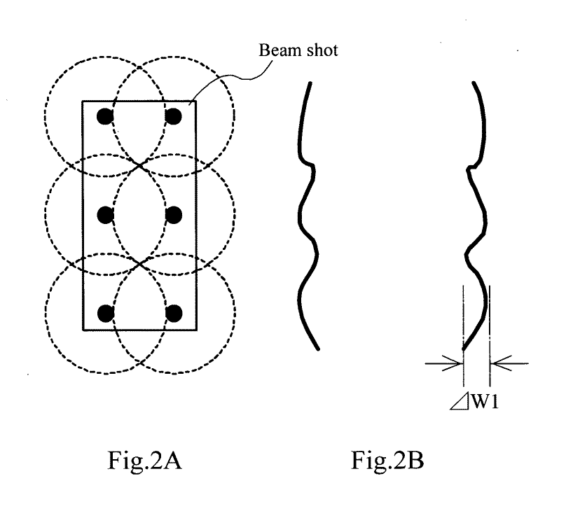

FIG. 2A shows schematic diagrams illustrating a typical situation example of the exposure reaction in a conventional chemical amplification type resist which formulates acid diffusion inhibitors of the usual amount. In FIG. 2A, the closed circle's acid generated by collision with electron or secondary electron in the square solid line area of an electron beam shot is reacted with dissolving inhibitors or cross-linking agents within the acid diffusion length. As a result, after the process developing the exposure pattern, the exposure envelop pattern as shown in dotted lines circles on the basis of mean diffusion radius in the diagram is attained like of FIG. 2B. In FIG. 2B, the solid lines indicate the drawing of parts of pattern edges and indicate envelope shapes attained from the outer of large circles of FIG. 2A, and therefore the edges' uneven width ΔW1 is relatively wide.

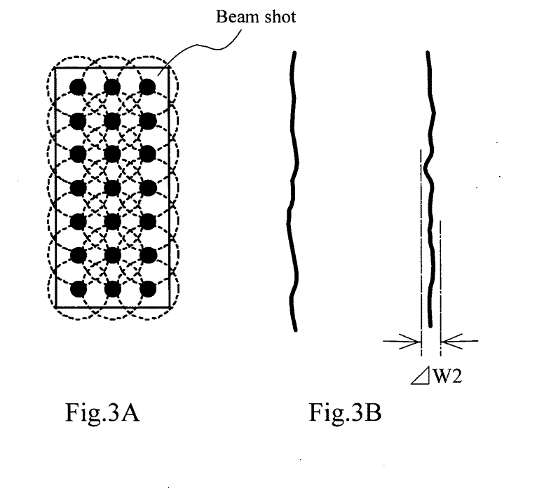

On the other hand, FIG. 3A is the present invention drawing. In this case, as the amount of acid diffusion inhibitors is increased, the mean diffusion length of the acid generated by means of the charged particle beam exposure is shorter than in the conventional case of FIG. 2A. In the present invention, as the irradiance per unit time of charged particle beams is increased, the probability of collisions between charged particles and acid generators is increased, and the amount of the acid generated is more than in the case of FIG. 2A. Therefore, as the solubilization or insolubilization of the resist by means of the charged particle exposure in the case shown FIG. 3A of the present invention is more in density than in the conventional case of FIG. 2A, the edge parts of the pattern produced by the process of this reaction are attained the envelope shapes from outer of dotted line circles of FIG. 3A, and have edge shapes close to the square solid line area of a electron beam shot.

When comparing the drawings of patterns in FIGS. 2A and B of conventional case and in FIGS. 3A and B of the present invention, it is clear that the conventional edge uneven width ΔW1 in the case of FIG. 2B and the edge uneven width ΔW2 of the present invention in the case of FIG. 3B have following relation, that is, ΔW1>ΔW2. Therefore, the pattern dimensional accuracy is improved in the present invention.

The following is the explanation of the pattern forming method by using the charged particle beam exposure of the present invention.

The pattern forming method of the present invention features, at least, a chemical amplification type resist coating process, a charged particle beam exposure process, a post exposure bake process, and a development process. And, upon request, a pre-bake process which remove organic solvent from the chemical amplification type resist layer between the above chemical amplification type resist coating process and the above charged particle beam exposure process could be practiced. And also, before chemical amplification type resist coating on the substrate of semiconductor etc; cleaning process of the surface on the substrate or reflection film forming process on the surface of the substrate could be practiced.

This pattern forming method is explained according to each process hereinafter.

Chemical Amplification Type Resist Coating Process:

This process is chemical amplification types resist coating process on the substrate of semiconductor, glass, and ceramics, etc.

In the resist coating process, known devices such as a spin coater, an applicator, a bar coater, a spinner, and a curtain flow coater are used.

The chemical amplification type resist materials used in this process are materials that dissolve in organic solvent. They are a base resin, a compound having acid decomposition group, and a polymerization inhibitor etc. In the chemical amplification type resist, there are two types. One is a positive type resist, of which charged particle beam exposure parts are solubilized in developer and holes are formed in the parts. The other one is a negative type resist, of which charged particle beam exposure parts are insolubilized in developer and holes are formed in the non-exposure parts. Materials used as a base resin of the resist are chosen accordingly, whether it is a positive or negative type resist.

In positive type resists, PMMA(poly-methyl-methacrylate) developed by mixed solvent of MIBK(methyl-isobutyl-ketone) and IPA(isopropyl alcohol) is well known, but recently, as the application of the process putting the importance to the reduction of incidence to environment as well as a resists performance increases, the alkali solubilization resin resist is used.

The resists containing the alkali solubilization resin adopt phenol resin, novolac resin, and substituted polystyrene etc.

The example of negative type resists is a compound which is accelerated either by cross-linking or polymerization by acids and is insolubilized in alkali developer, such as alkyl-etherification melamine resin, alkyl-etherification benzoguanamine resin, alkyl-etherification urea resin, and phenolic compound having alkyl-ether group etc.

A charged particle exposure acid generator and a thermo-acid generator are known well as acid generators. The former is dissociated by exposure of charged particles and generates an acid (usually known as PAG (photo acid generator)). The latter generates an acid by heating.

Examples of charged particle exposure acid generators are bis-sulfonyl-diazomethane class, nitro-benzyl derivative, poly-hydroxy compound and aliphatic or aromatic sulfonate class, onium salt, sulfonyl-carbonyl-alkane class, sulfonyl-carbonyl-diazomethane class, halogenated triazine compound class, oxime-sulfonate compound class, and phenyl-sulfonyl-oxy-phthalimide class etc.

Among examples of thermo-acid generators, sulfonimid is known. It generate an acid in the range of 140˜150 degrees Centigrade.

In the present invention, adding amount of an acid generator should be in the range of 0.1˜30 weight percent (wt %) to all solid content of the resist. When the adding amount of an acid generator decrease beyond the said wt % range, the sensitivity of the charged particle beam exposure is decreased and it is difficult to form resist patterns. On the other hand when the adding amount of an acid generator increase beyond the said wt % range, the decay of the charged particles become excessive and it is difficult to form requested resist patterns.

In the present invention, it is necessary to add an acid diffusion inhibitor to chemical amplification type resist materials. The acid diffusion inhibitor protects the resist pattern profile from disorder by excessive diffusion of the acid generated from acid generator within the chemical amplification type resist. Usually it is added to the area where the influence of the acid catalyst generated by the light exposure should be controlled. Specifically, when the charged particle beam is exposed to the resist layer, and reflection of the charged particle beam from the substrate exposes the bottom area of resist excessively, the acid diffusion inhibitor is used. In this case, by adding the acid diffusion inhibitor, the catalytic reaction of the acid catalyst is inhibited, and the reaction in the resist is suppressed. Therefore, the amount of the acid diffusion inhibitor is determined in consideration of resist profile abnormality caused under the condition of not adding any acid diffusion inhibitor.

In the present invention, adding amount of the acid diffusion inhibitor much exceeds the conventional adding amount. In the present invention, the favorable adding amount is 2˜10 times more than the conventional amount.

In order to achieve excellent accuracy resist patterns, it is preferable that an adding amount ratio of the said acid diffusion inhibitor is in the range of 0.01˜30 mol % for a photo acid generator of the chemical amplification type resist, where the photo acid generator is the material which generate an acid either through the light or the charged particle beam exposure. In the present invention, as an acid diffusion inhibitor, an alkaline material, or the material that could generate an alkaline material by a charged particle beam exposure is used. Practically, tertiary amine class, benzyl-carbamate class, benzoin-carbamate class, o-carbamoyl-hydroxy-amine class, o-carbamoyl-oxime class, dithio-calbamate-quaternary ammonium salt etc are used.

Pre-Bake Process:

The substrate coated with the chemical amplification type resist in above process is pre-baked, and volatile elements like solvent existing in the resist are removed from the substrate. Usually, the pre-bake process is done at the temperature of 80˜140 degrees Centigrade, about 60 seconds for the wafer substrate and about 10 minutes for the mask. As the developing performance of the chemical amplification type resist is influenced by the pH of the circumstances, it is preferable that the atmosphere of the pre-bake process contains no acidic materials or alkaline materials.

Charged Particle Beam Exposure Process:

Next, patterns are written on the substrate by using the charged particle beam exposure system. As charged particles such as electron beam (EB) are exposed to the chemical amplification type resist, acids are dissociated and generated from acid generators which are formulated in the chemical amplification type resist, and either solubilization reaction or insolubilization reaction is occurred by acids. In the present invention, as an example of charged particle beams, an electron beam is used. However, the beam is not necessarily limited to electron beam. Other kind of beam such as ion beam is available, as long as it generates solubility change in the chemical amplification type resist materials.

As one of the charged particle beam exposure system in the present invention, the known electron beam exposure system could be used, if it enables the current density of electron beams to be increased.

We will explain the electron beam exposure system briefly by using drawings as follows.

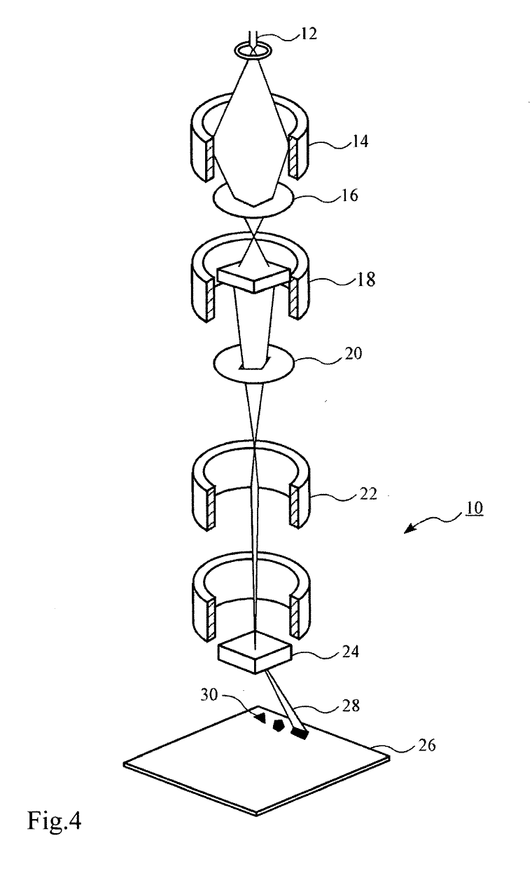

FIG. 4 shows an example of the electron beam exposure system as the embodiment of the present invention. In FIG. 4, an electron beam exposure system 10 comprises, an electron gun 12, a first lens 14 and a first shaping aperture 16 to form a required shape electron beams emitted and accelerated from an electron gun 12, a second lens 18 and a second shaping aperture 20 to form further the electron beams' shape, a reducing lens 22 to reduce the size of the electron beams, and a deflector 24 to control the irradiation direction of the electron beams. This electron beams irradiated from the deflector 24 are exposed on a treating substrate 26, and patterns 30 are written on a resist layer on the substrate. Housing, not shown in the FIG. 4, covers this electron beam exposure system 10 and the treating substrate 26 and the inside of the housing is kept in a vacuum. And also, a controller, not shown in the FIG. 4, controls the operation of the whole system.

In this electron beam exposure system 10, the electron gun 12 and the first lens 14 control the current density.

In the present invention, as the increased amount of acid diffusion inhibitors is added to the said chemical amplification type resist, the diffusion of acids generated by the exposure are inhibited, and the reaction of solubilization or insolubilization in the chemical amplification type resist is disturbed. In order to have an expected reaction of solubilization or insolubilization in the chemical amplification type resists, it is necessary increasing the beam dosage (exposure amount) per unit area of the treating substrate.

The dosage of charged particle beams D is described as D=J·T, where J is the exposure current density in proportion to the amount of charged particle beams, and T is the exposure time of charged particle beams. If the exposure current density increases, it is possible to increase the dosage without growing exposure time. Therefore, as the exposure current density increases from the prescribed setting value, above-mentioned reaction is achieved without growing the exposure time which influences the throughput.

The increasing rate of the exposure current density depends on the acid diffusion inhibitor amount in the chemical amplification type resist. If the chemical amplification resist has the acid diffusion inhibitor amount that results in reducing the mean acid diffusion length by half, the exposure current density should be doubled approximately.

Post Exposure Bake Process

Next, the post exposure bake process is done. The reaction of solubilization or insolubilization in the chemical amplification type resist occurs in this process. In the process using chemical amplification type resists, bake process is performed after exposure, and the diffusion of the acids and the catalytic reaction of acids which are generated from acid generators in chemical amplification type resists occur.

The baking temperature should be in the range of 70-150 degrees Centigrade. When the baking temperature is lower than this range, pattern forms and resolution deteriorate.

Development Process

The development process is the process actualizing latent images that is formed on the resist layer of the substrate in above prior processes. Generally, the resist layer is processed using alkaline developer, and non-hardening parts of the resist are removed. The hardening parts, in the case of positive type resists, are charged particle beams exposure parts, and by the alkaline developer, the resist parts are solubilized, and the resist parts are removed. On the other hand, in the case of negative type resists, exposure parts of the resist materials are insolubilized by the cross-linked reaction etc. As non-exposure parts of the resists are solubilized, the parts of the resists are removed.

Usually, tetra-methyl-ammonium hydroxide (TMAH) and other alkaline solution are used as the developer.

After that, resist patterns are dried, and the resultant pattern formed on the substrate is obtained.

### EXAMPLE

### Example 1

Chromium oxide having a film thickness of 30 nm (300 Å) and chromium having a film thickness of 70 nm (700 Å) were formed on a glass substrate and a substrate for a 6-inch mask was produced. 92.4 parts by weight of polyvinyl-phenolic resin, which is, introduced a substituent having insolubilization effect on a side chain,

7 parts of weight of succinimidyl-trifluoro-methane-sulfonate of an acid generator, and 0.6 parts of weight of o-nitrobenzyl-carbamate of an acid diffusion inhibitor were formulated and were dissolved to organic solvent and were formed a chemical amplification type resist.

The said chemical amplification type resist was coated on the surface of the said substrate by means of a spin coater, and was pre-baked with the temperature of 110 degrees Centigrade for 600 seconds and the resist layer of thickness of 300 nm (3000 Å) was prepared.

Next step, by using a electron beam exposure system of accelerating voltage of 50 kV and the maximum beam size of 1 μm square, pattern exposure was performed with the electron beams. The exposure dose was 20 μC/cm² and the current density was 100 A/cm². And also, pattern widths were 500 nm and 100 nm.

Next step, the substrate was placed on the hotplate, and the resist layer on the substrate was heated with the temperature of 120 degrees Centigrade for 900 seconds, and latent images were formed on the resist layer. After that, by using 2.38 wt % of tetra-methyl-ammonium-hydroxide (TMAH) aqueous solution, at the temperature of 23 degrees Centigrade for 60 seconds development processing was performed.

### Example 2

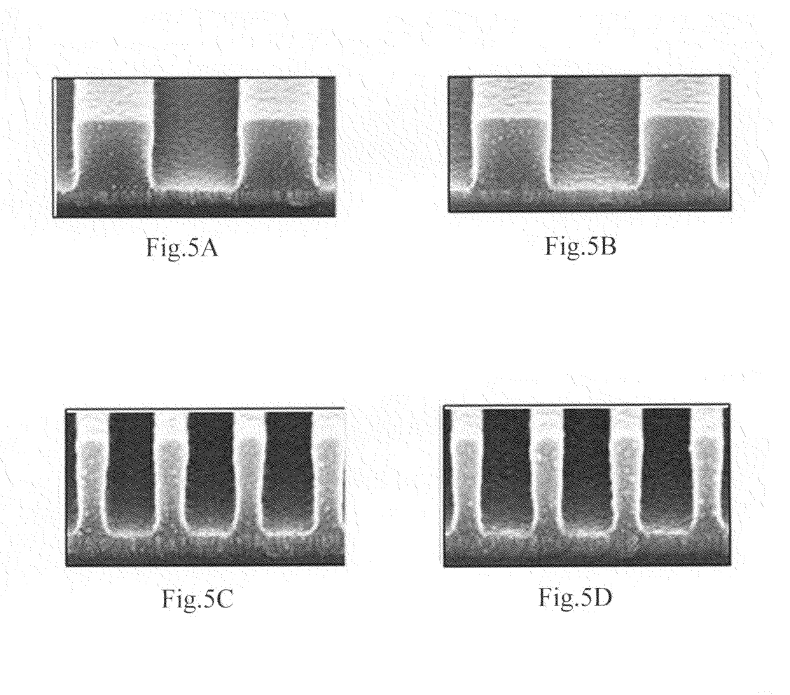

Further, an acid diffusion inhibitor amount was increased from 0.6 parts by weight in example 1 to 1.2 parts by weight in example 2, and patterns were written by means of the same process as example 1. The result was shown in FIG. 5B and FIG. 5D together with the result of the example 1.

(Evaluation)

With respect to the patterns obtained from example 1 and example 2, LCD accuracy (3σ), which is defined as CD variation in the area of about 100 μm square, was measured. And also, LER (line edge roughness) accuracy was measured. The result is shown in table 1.

TABLE 1

| | Acid diffusion | | LER |
|---|---|---|---|
| Example | inhibitor | LCD accuracy | accuracy |
| No. | Amount rate | (3σ) | (Max error) |
| Example 1 | 0.6 parts by | 1.4 nm | 2.5 nm |
| | weight | | |
| Example 2 | 1.2 parts by | 1.0 nm | 2.0 nm |
| | weight | | |

The cross sectional profile of patterns obtained from example 1 and example 2 is shown in FIG. 5A to FIG. 5D. These cross sectional profiles were taken by SEM (Scanning Electron Microscope).

FIG. 5A and FIG. 5B show the cross sectional profile of 500 nm width pattern obtained from the example 1 and the example 2, respectively. FIG. 5C and FIG. 5D show the cross sectional profile of 100 nm width pattern obtained from the example 1 and the example 2, respectively.

As the amount of the acid diffusion inhibitor increases, both corners of the resist top become sharper and the footing on the substrate surface becomes smaller. Moreover the middle part of the resist wall becomes thicker. As a result, no collapse of the fine pattern occurs in the example 1 and example 2.

In this way, it became clear that as the amount of the acid diffusion inhibitor increases, the pattern accuracy and profile improve. Increasing the current density increases the dosage. It is possible to increase dosage (exposure amount) by adopting higher current density. Therefore excellent performance of electron beam writing system can be attained without throughput loss.

What is claimed is:

1. A electron beam lithography method on a chemical amplification type resist, comprising:
coating said chemical amplification type resist which contains an acid diffusion inhibitor, on a surface of a mask substrate,
exposing electron beams to said chemical amplification type resist layer on said surface of the mask substrate,
baking said chemical amplification type resist layer which said electron beams were exposed,
and developing said chemical amplification type resist after the baking,
wherein an exposure current density of said electron beams exposing ranges of 50^{˜}5000 A/cm²,
said photo acid generator is in an amount ranging from 0.1 to 30 weight percent (wt %) relative to all solid content of said chemical amplification type resist, and
said acid diffusion inhibitor is composed of at least one material selected from the group consisting of tertiary amine class, benzyl-carbamate class, benzoin-carbamate class, o-carbamoyl-hydroxy-amine class, o-carbamoyl-oxime class, and dithio-calbamate-quaternary ammonium salt.

2. The lithography method according to claim 1, wherein an alkaline developer is used in the development process to actualize latent images, which are formed on said resist.
